(19) United States
(12) Patent Application Publication
(10) Pub. No.: US 2026/0152856 A1
(43) Pub. Date: Jun. 4, 2026

(54) FILM FORMING APPARATUS

(71) Applicant: Tokyo Electron Limited, Tokyo (JP)

(72) Inventors: Kentaro TAKATORI, Boise, ID (US); Tsuyoshi TAKAHASHI, Gyeonggi-do (KR)

(21) Appl. No.: 19/428,978

(22) Filed: Dec. 22, 2025

Related U.S. Application Data
(63) Continuation of application No. PCT/JP2024/023038, filed on Jun. 25, 2024.

(30) Foreign Application Priority Data
Jul. 7, 2023 (JP) 2023-112005

(51) Int. Cl. C23C 16/52; C23C 16/30; C23C 16/455

(52) U.S. Cl. CPC C23C 16/52; C23C 16/303; C23C 16/45561

(57) ABSTRACT

A film forming apparatus for supplying a first source gas, a second source gas, and a reaction gas into a processing chamber is provided. The film forming apparatus includes a gas supply timing adjustment mechanism configured to simultaneously supply the first source gas and the second source gas into the processing chamber, and a controller configured to control the gas supply timing adjustment mechanism.

### CROSS-REFERENCE TO RELATED APPLICATION

This application is a continuation of International Application No. PCT/JP2024/023038, filed on Jun. 25, 2024 and designating the U.S., which claims priority to Japanese Patent Application No. 2023-112005, filed on Jul. 7, 2023. The contents of these applications are incorporated herein by reference in their entirety.

### TECHNICAL FIELD

The present disclosure relates to a film forming apparatus.

### BACKGROUND ART

Japanese Laid-open Patent Publication No. 2020-74367 describes a method of manufacturing a semiconductor device, including forming, on a substrate, a film containing a metal element, another element different from the metal element, and nitrogen by performing a cycle a predetermined number of times. The cycle includes non-simultaneously performing: a first step of supplying a first source gas containing the metal element and a halogen element and a second source gas containing the other element and hydrogen to the substrate while evacuating a space in which the substrate is disposed, such that supply periods of the first source gas and the second source gas at least partially overlap with each other; a removal step of removing the first source gas, the second source gas, and a by-product generated in the first step from the space in which the substrate is disposed after the first step; and a second step of supplying a reaction gas containing nitrogen to the substrate while exhausting the space in which the substrate is disposed after the removal step.

Japanese Laid-open Patent Publication No. 2021-31686 describes a method of forming a metal-containing nitride film containing silicon. The method includes a step of supplying a metal-containing gas into a processing chamber in which a substrate is accommodated, a step of supplying a silicon-containing gas into the processing chamber; and a step of supplying a nitrogen-containing gas into the processing chamber. After the step of supplying the metal-containing gas and the step of supplying the silicon-containing gas are performed n times (n is an integer of one or more) in this order, the step of supplying the nitrogen-containing gas is repeated m times (m is an integer of one or more).

### SUMMARY

According to an aspect of the present disclosure, a film forming apparatus for supplying a first source gas, a second source gas, and a reaction gas into a processing chamber is provided. The film forming apparatus includes a gas supply timing adjustment mechanism configured to simultaneously supply the first source gas and the second source gas into the processing chamber, and a controller configured to control the gas supply timing adjustment mechanism.

### BRIEF DESCRIPTION OF THE DRAWINGS

FIG. 1 is an example of a cross-sectional view illustrating a configuration of a film forming apparatus according to a first embodiment;

FIG. 2 is a flowchart illustrating an example of a film forming method of a TiSiN film according to an embodiment;

FIG. 3 is a time chart illustrating an example of timings of gas supply in the film forming method according to the embodiment;

FIG. 4 is an example of a configuration diagram of a gas supply timing adjustment mechanism of the film forming apparatus according to the first embodiment;

FIG. 5 is an example of a configuration diagram of a gas supply timing adjustment mechanism of a film forming apparatus according to a reference example;

FIG. 6A is a time chart illustrating an example of timings of gas supply in a film forming method according to the reference example;

FIG. 6B is a time chart illustrating an example of timings of gas supply in the film forming method according to the reference example;

FIG. 7 is an example of a configuration diagram of a gas supply timing adjustment mechanism of a film forming apparatus according to a second embodiment;

FIG. 8 is an example of a configuration diagram of a gas supply timing adjustment mechanism of a film forming apparatus according to a third embodiment;

FIG. 9 is an example of a configuration diagram of a gas supply timing adjustment mechanism of a film forming apparatus according to a fourth embodiment;

FIG. 10 is a time chart illustrating an example of timings of gas supply in a film forming method performed by the film forming apparatus according to the fourth embodiment;

FIG. 11 is a schematic cross-sectional view illustrating an example of a film formed on a substrate in another film forming method performed by the film forming apparatus according to the fourth embodiment;

FIG. 12 is an example of a configuration diagram of a gas supply timing adjustment mechanism of a film forming apparatus according to a fifth embodiment; and

FIG. 13 is an example of a configuration diagram of a gas supply timing adjustment mechanism of a film forming apparatus according to a sixth embodiment.

### DETAILED DESCRIPTION

Embodiments of the present disclosure will be described below with reference to the drawings. In the drawings, the same components are denoted by the same reference numerals, and a duplicate description thereof may be omitted.

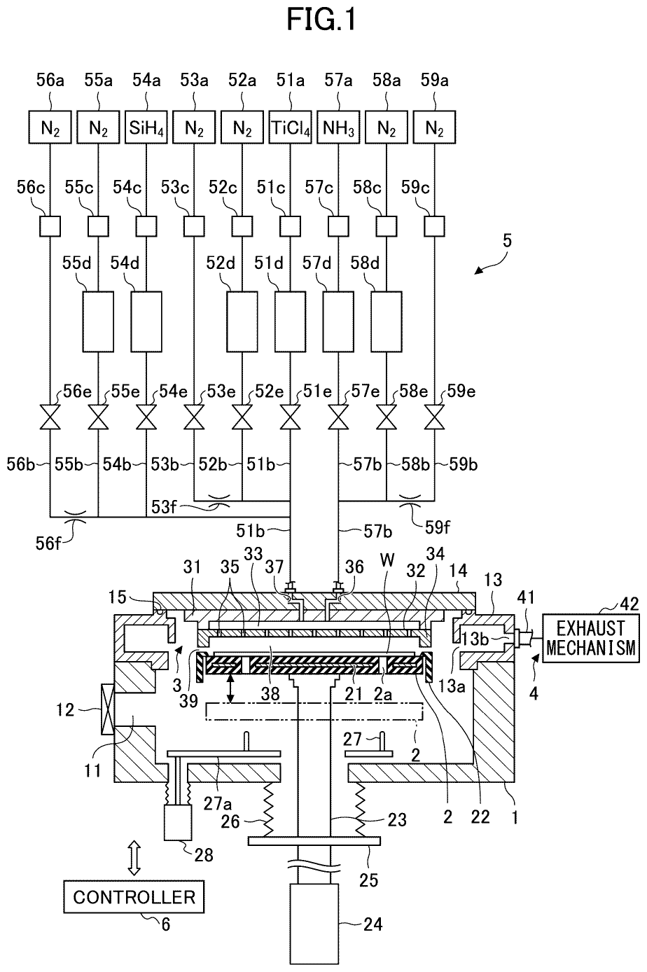

An example of a film forming apparatus according to a first embodiment will be described with reference to FIG. 1. FIG. 1 is an example of a cross-sectional view illustrating a configuration of the film forming apparatus according to the first embodiment.

The film forming apparatus is a film forming apparatus configured to supply a plurality of process gases into a processing chamber 1 and perform a film forming process on a substrate W by an atomic layer deposition (ALD) method. In the following description, an example in which a first source gas (a first process gas), a second source gas (a second process gas), and a reaction gas (a third process gas) are used as the process gases will be described.

The first source gas is a gas containing a first element. Further, the first source gas is, for example, a metal-containing gas containing a metal element. For example, the first source gas is a Ti-containing gas containing a titanium (Ti) element. Note that the first source gas is not limited thereto.

The second source gas is a gas containing a second element different from the first element. For example, the second source gas is a Si-containing gas containing a silicon (Si) element. Note that the second source gas is not limited to thereto.

The reaction gas is, for example, a gas reacting with the first source gas and/or the second source gas. For example, the reaction gas is a nitrogen-containing gas (nitriding gas) containing a nitrogen (N) element and nitriding the first source gas and/or the second source gas. Note that the reaction gas is not limited thereto. The reaction gas may be an oxygen-containing gas (oxidizing gas) containing an oxygen (O) element and oxidizing the first source gas and/or the second source gas.

In the following description, an example in which the first source gas is TiCl₄ gas, the second source gas is SiH₄ gas, the reaction gas is NH₃ gas, and the film forming apparatus forms a TiSiN film will be described.

The film forming apparatus includes the processing chamber 1, a stage 2, a showerhead 3, an exhaust 4, a gas supply mechanism 5, and a controller 6.

The processing chamber 1 is formed of a metal such as aluminum, and has substantially a cylindrical shape. The processing chamber 1 accommodates the substrate W such as a wafer to be processed. A loading and unloading port 11 for loading and unloading the substrate W is formed in a side wall of the processing chamber 1. The loading and unloading port 11 is opened and closed by a gate valve 12. An annular exhaust duct 13 having a rectangular cross-sectional shape is disposed above the main body of the processing chamber 1. A slit 13a is formed along the inner peripheral surface of the exhaust duct 13. An exhaust port 13b is formed in the outer wall of the exhaust duct 13. A ceiling 14 is disposed on the upper surface of the exhaust duct 13 to cover an upper opening of the processing chamber 1. A space between the exhaust duct 13 and the ceiling 14 is airtightly sealed by a seal ring 15.

The stage 2 horizontally supports the substrate W in the processing chamber 1. The stage 2 is formed in a disc shape having a size corresponding to the substrate W. The stage 2 is formed of a ceramic material such as aluminum nitride (AlN), or a metal material such as aluminum or a nickel alloy. A heater 21 for heating the substrate W is embedded in the stage 2. A heater power supply (not illustrated) supplies electricity to the heater 21 to generate heat. The temperature of the substrate W is controlled at a predetermined temperature by controlling the output of the heater 21 according to a temperature signal of a thermocouple (not illustrated) disposed in the vicinity of the upper surface of the stage 2. A cover member 22 formed of a ceramic such as alumina is provided so as to over an outer peripheral region of the upper surface and a side surface of the stage 2.

A support member 23 supporting the stage 2 is provided on the bottom surface of the stage 2. The support member 23 extends from the center of the bottom surface of the stage 2 to the lower side of the processing chamber 1 through a hole formed in a bottom wall of the processing chamber 1, and the lower end of the support member 23 is connected to a lifting and lowering mechanism 24. The stage 2 is lifted and lowered by the lifting and lowering mechanism 24 via the support member 23 between a processing position illustrated in FIG. 1 and a transfer position, indicated by a two-dot dash line, below the processing position at which the substrate W can be transferred. A flange 25 is attached to the support member 23 below the processing chamber 1. A bellows 26 that separates the atmosphere in the processing chamber 1 from the outside air and expands and contracts according to the lifting and lowering operation of the stage 2 is provided between the bottom surface of the processing chamber 1 and the flange 25.

Three substrate support pins 27 (only two of which are illustrated) are provided in the vicinity of the bottom surface of the processing chamber 1 so as to protrude upward from a lifting and lowering plate 27a. The substrate support pins 27 are lifted and lowered via the lifting and lowering plate 27a by a lifting and lowering mechanism 28 provided below the processing chamber 1. The substrate support pins 27 are inserted into through-holes 2a provided in the stage 2 at the transfer position so as to be projected and retracted with respect to the upper surface of the stage 2. By lifting and lowering the substrate support pins 27, the substrate W is transferred between a transfer mechanism (not illustrated) and the stage 2.

The showerhead 3 supplies a processing gas into the processing chamber 1 in the form of a shower. The showerhead 3 is formed of a metal, provided so as to face the stage 2, and has substantially the same diameter as the stage 2. The showerhead 3 includes a plate support 31 and a shower plate 32. The plate support 31 is fixed onto the ceiling 14 of the processing chamber 1, and the shower plate 32 is connected to the bottom of the plate support 31. A gas diffusion space 33 is formed between the plate support 31 and the shower plate 32. Gas inlet holes 36 and 37 are provided in the gas diffusion space 33 so as to penetrate through the center of the ceiling 14 of the processing chamber 1 and the center of the plate support 31. An annular projection 34 projecting downward is formed on the peripheral edge of the shower plate 32. Gas discharge holes 35 are formed in a flat surface of the shower plate 32 located inward of the annular projection 34. With the stage 2 being located at the processing position, a processing space 38 is formed between the stage 2 and the shower plate 32 and the annular projection 34 is close to the upper surface of the cover member 22, thereby forming an annular gap 39.

The exhaust 4 exhausts gas from the inside of the processing chamber 1. The exhaust 4 includes an exhaust pipe 41 connected to the exhaust port 13b, and an exhaust mechanism 42 connected to the exhaust pipe 41. The exhaust mechanism 42 includes a vacuum pump, a pressure control valve, and the like. During processing, the gas inside the processing chamber 1 passes through the slit 13a to reach the exhaust duct 13, and the gas is exhausted from the exhaust duct 13 by the exhaust mechanism 42 through the exhaust pipe 41.

The gas supply mechanism 5 supplies processing gases into the processing chamber 1. The gas supply mechanism 5 includes a first source gas supply source 51a, an N₂ gas supply source 52a, an N₂ gas supply source 53a, a second source gas supply source 54a, an N₂ gas supply source 55a, an N₂ gas supply source 56a, a reaction gas supply source 57a, an N₂ gas supply source 58a, and an N₂ gas supply source 59a.

The first source gas supply source 51a supplies TiCl₄ gas, which is an example of the first source gas (first process gas, metal-containing gas, or Ti-containing gas), into the processing chamber 1 via a gas supply line 51b. The gas supply line 51b is provided with a flow rate controller 51c, a storage tank 51d, and a valve 51e in this order from the upstream side. The downstream side of the gas supply line 51b relative to the valve 51d is connected to the gas inlet hole 37. The TiCl₄ gas supplied from the first source gas supply source 51a is temporarily stored in the storage tank 51d before being supplied into the processing chamber 1, is pressurized to a predetermined pressure in the storage tank 51e, and is then supplied into the processing chamber 1. The supply and stop of the TiCl₄ gas from the storage tank 51d into the processing chamber 1 are performed by the valve 51e. Because the TiCl₄ gas is temporarily stored in the storage tank 51d as described above, the TiCl₄ gas can be stably supplied into the processing chamber 1 at a relatively high flow rate.

The N₂ gas supply source 52a supplies N₂ gas, which is an example of a purge gas, into the processing chamber 1 via a gas supply line 52b. The gas supply line 52b is provided with a flow rate controller 52c, a storage tank 52d, and a valve 52e in this order from the upstream side. The downstream side of the gas supply line 52b relative to the valve 52e is connected to the gas supply line 51b. The N₂ gas supplied from the N₂ gas supply source 52a is temporarily stored in the storage tank 52d before being supplied into the processing chamber 1, is pressurized to a predetermined pressure in the storage tank 52d, and is then supplied into the processing chamber 1. The supply and stop of the N₂ gas from the storage tank 52d into the processing chamber 1 are performed by the valve 52e. Because the N₂ gas is temporarily stored in the storage tank 52d as described above, the N₂ gas can be stably supplied into the processing chamber 1 at a relatively high flow rate.

The N₂ gas supply source 53a supplies N₂ gas, which is an example of a carrier gas, into the processing chamber 1 via a gas supply line 53b. The gas supply line 53b is provided with a flow rate controller 53c, a valve 53e, and an orifice 53f in this order from the upstream side. The downstream side of the gas supply line 53b relative to the orifice 53f is connected to the gas supply line 51b. The N₂ gas supplied from the N₂ gas supply source 53a is continuously supplied into the processing chamber 1 during film formation on the substrate W. The supply and stop of the N₂ gas from the N₂ gas supply source 53a into the processing chamber 1 are performed by the valve 53e. The orifice 53f prevents the gases supplied from the storage tanks 51d and 52d to the gas supply lines 51b and 52b at a relatively high flow rate from flowing backward into the gas supply line 53b.

The second source gas supply source 54a supplies SiH₄ gas, which is an example of the second source gas (second process gas or Si-containing gas), into the processing chamber 1 via a gas supply line 54b. The gas supply line 54b is provided with a flow rate controller 54c, a storage tank 54d, and a valve 54e in this order from the upstream side. The downstream side of the gas supply line 54b relative to the valve 54e is connected to the gas supply line 51b. The SiH₄ gas supplied from the second source gas supply source 54a is temporarily stored in the storage tank 54d before being supplied into the processing chamber 1, is pressurized to a predetermined pressure in the storage tank 54d, and is then supplied into the processing chamber 1. The supply and stop of the SiH₄ gas from the storage tank 54d into the processing chamber 1 are performed by the valve 54e. Because the SiH₄ gas is temporarily stored in the storage tank 54d as described above, the SiH₄ gas can be stably supplied into the processing chamber 1 at a relatively high flow rate.

The N₂ gas supply source 55a supplies N₂ gas, which is an example of the purge gas, into the processing chamber 1 via a gas supply line 55b. The gas supply line 55b is provided with a flow rate controller 55c, a storage tank 55d, and a valve 55e in this order from the upstream side. The downstream side of the gas supply line 55b relative to the valve 55e is connected to the gas supply line 51b. The N₂ gas supplied from the second source gas supply source 55a is temporarily stored in the storage tank 55d before being supplied into the processing chamber 1, is pressurized to a predetermined pressure in the storage tank 55d, and is then supplied into the processing chamber 1. The supply and stop of the N₂ gas from the storage tank 55d into the processing chamber 1 are performed by the valve 55e. Because the N₂ gas is temporarily stored in the storage tank 55d as described above, the N₂ gas can be stably supplied into the processing chamber 1 at a relatively high flow rate.

The N₂ gas supply source 56a supplies N₂ gas, which is an example of the carrier gas, into the processing chamber 1 via a gas supply line 56b. The gas supply line 56b is provided with a flow rate controller 56c, a valve 56e, and an orifice 56f in this order from the upstream side. The downstream side of the gas supply line 56b relative to the orifice 56f is connected to the gas supply line 51b. The N₂ gas supplied from the N₂ gas supply source 56a is continuously supplied into the processing chamber 1 during film formation on the substrate W. The supply and stop of the N₂ gas from the N₂ gas supply source 56a into the processing chamber 1 are performed by the valve 56e. The orifice 56f prevents the gases supplied from the storage tanks 54d and 55d to the gas supply lines 54b and 55b at a relatively high flow rate from flowing backward into the gas supply line 56b.

The reaction gas supply source 57a supplies NH₃ gas, which is an example of the reaction gas (third process gas or nitrogen-containing gas), into the processing chamber 1 via a gas supply line 57b. The gas supply line 57b is provided with a flow rate controller 57c, a storage tank 57d, and a valve 57e in this order from the upstream side. The downstream side of the gas supply line 57b relative to the valve 57e is connected to the gas inlet hole 36. The NH₃ gas supplied from the reaction gas supply source 57a is temporarily stored in the storage tank 57d before being supplied into the processing chamber 1, is pressurized to a predetermined pressure in the storage tank 57d, and is then supplied into the processing chamber 1. The supply and stop of the NH₃ gas from the storage tank 57d into the processing chamber 1 are performed by the valve 57e. Because the NH₃ gas is temporarily stored in the storage tank 57d as described above, the NH₃ gas can be stably supplied into the processing chamber 1 at a relatively high flow rate.

The N₂ gas supply source 58a supplies N₂ gas, which is an example of the purge gas, into the processing chamber 1 via a gas supply line 58b. The gas supply line 58b is provided with a flow rate controller 58c, a storage tank 58d, and a valve 58e in this order from the upstream side. The downstream side of the gas supply line 58b relative to the valve 58e is connected to the gas supply line 57b. The N₂ gas supplied from the N₂ gas supply source 58a is temporarily stored in the storage tank 58d before being supplied into the processing chamber 1, is pressurized to a predetermined pressure in the storage tank 58d, and is then supplied into the processing chamber 1. The supply and stop of the N₂ gas from the storage tank 58d into the processing chamber 1 are performed by the valve 58e. Because the N₂ gas is temporarily stored in the storage tank 58d as described above, the N₂ gas can be stably supplied into the processing chamber 1 at a relatively high flow rate.

The N₂ gas supply source 59a supplies N₂ gas, which is an example of the carrier gas, into the processing chamber 1 via a gas supply line 59b. The gas supply line 59b is provided with a flow rate controller 59c, a valve 59e, and an orifice 59f in this order from the upstream side. The downstream side of the gas supply line 59b relative to the orifice 59f is connected to the gas supply line 57b. The N₂ gas supplied from the N₂ gas supply source 59a is continuously supplied into the processing chamber 1 during film formation on the substrate W. The supply and stop of the N₂ gas from the N₂ gas supply source 59a into the processing chamber 1 are performed by the valve 59e. The orifice 59f prevents the gases supplied from the storage tanks 57d and 58d to the gas supply lines 57b and 58b at a relatively high flow rate from flowing backward into the gas supply line 59b.

The controller 6 is, for example, a computer, and includes a central processing unit (CPU), a random access memory (RAM), a read only memory (ROM), an auxiliary storage device, and the like. The CPU operates based on a program stored in the ROM or the auxiliary storage device, and controls operations of the film forming apparatus. The controller 6 may be provided inside or outside the film forming apparatus. When the controller 6 is provided outside the film forming apparatus, the controller 6 can control the film forming apparatus by a communication system such as a wired or wireless communication system.

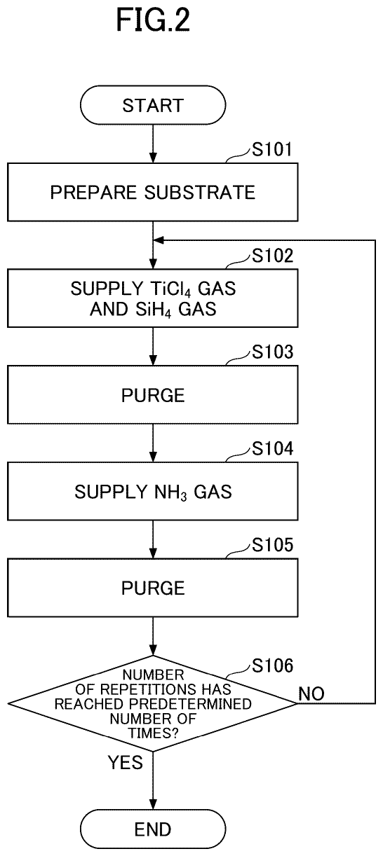

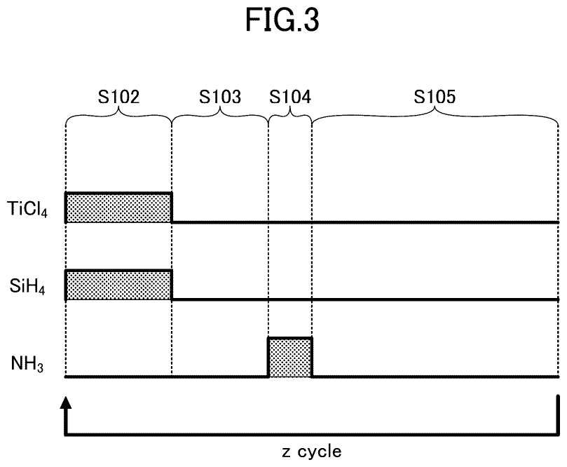

Next, an example of a film forming method according to an embodiment will be described with reference to FIGS. 2 and 3. FIG. 2 is a flowchart illustrating an example of a film forming method of a TiSiN film according to an embodiment. FIG. 3 is a time chart illustrating an example of timings of gas supply in the film forming method according to the embodiment.

In step S101, a substrate W is prepared.

First, with the valves 51e to 59e being closed, the gate valve 12 is opened to transfer the substrate W into the processing chamber 1 by the transfer mechanism (not illustrated), and the substrate W is placed on the stage 2 at the transfer position. After the transfer mechanism is retracted from the processing chamber 1, the gate valve 12 is closed.

The controller 6 controls the heater 21 of the stage 2 to heat the substrate W to a predetermined temperature (for example, any temperature in the range of 300° C. to 700° C.). Further, the controller 6 controls the lifting and lowering mechanism 24 to lift the stage 2 to the processing position, thereby forming the processing space 38. Further, the controller 6 controls the pressure control valve of the exhaust mechanism 42 to adjust the pressure in the processing chamber 1 to a predetermined pressure (for example, 100 Pa to 3,000 Pa (0.75 torr to 22.5 torr)).

Next, the controller 6 opens the valves 53e, 56e, and 59e. As a result, the carrier gas (N₂ gas) is supplied into the processing chamber 1 at a predetermined flow rate from the N₂ gas supply sources 53a, 56a, and 59a through the gas supply lines 53b, 56b, and 59b, respectively, and through the gas supply lines 51b and 57b.

Further, TiCl₄ gas, SiH₄ gas, and NH₃ gas are supplied from the first source gas supply source 51a, the second source gas supply source 54a, and the reaction gas supply source 57a to the gas supply lines 51b, 54b, and 57b, respectively. At this time, the valves 51e, 54e, and 57e are closed. Thus, the TiCl₄ gas, the SiH₄ gas, and the NH₃ gas are stored in the storage tanks 51d, 54d, and 57d, respectively, and the pressure in the storage tanks 51d, 54d, and 57d is increased.

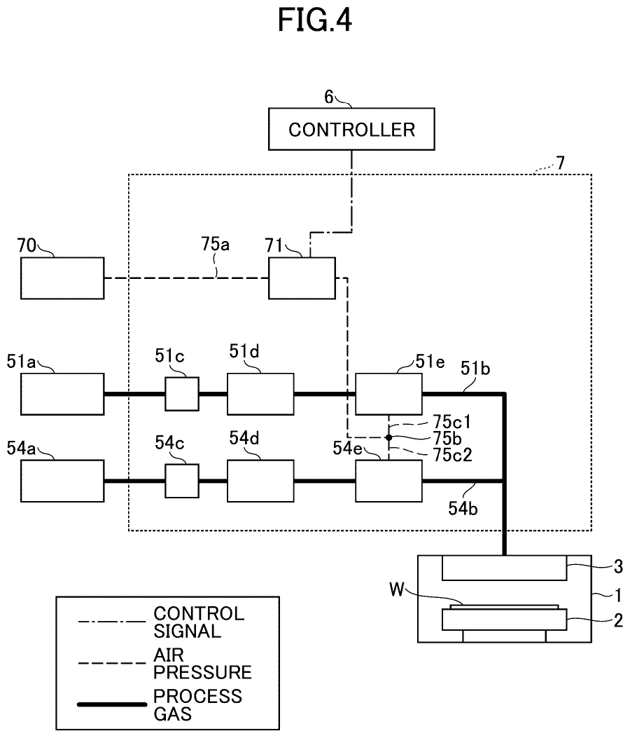

In step S102, the TiCl₄ gas (first source gas) and the SiH₄ gas (second source gas) are supplied into the processing chamber 1. The controller 6 uses a gas supply timing adjustment mechanism 7 (see FIG. 4), which will be described later, to simultaneously open the valve 51e and the valve 54e and simultaneously supply the TiCl₄ gas and the SiH₄ gas into the processing chamber 1. Thus, the TiCl₄ gas stored in the storage tank 51d and the SiH₄ gas stored in the storage tank 54d are simultaneously supplied into the processing chamber 1, and the first source gas and the second source gas are adsorbed on the substrate W.

Concurrently with the supply of the TiCl₄ gas and the SiH₄ gas into the processing chamber 1, the purge gas (N₂ gas) is supplied from the N₂ gas supply sources 52a, 55a, and 58a to the gas supply lines 52b, 55b, and 58b. At this time, the valves 52e, 55e, and 58e are closed. Thus, the purge gas is stored in the storage tanks 52d, 55d, and 58d, and the pressure in the storage tanks 52d, 55d, and 58d is increased.

After a predetermined processing time (for example, 0.01 seconds to 5 seconds) has elapsed after the valves 51e and 54e are opened, the controller 6 closes the valves 51e and 54e.

In step S103, the purge gas is supplied into the processing chamber 1 to purge the gases in the processing chamber 1. In this step, the controller 6 opens the valves 52e, 55e, and 58e. Thus, the purge gas stored in each of the storage tanks 52d, 55d, and 58d is supplied into the processing chamber 1. At this time, because the purge gas is supplied from the storage tanks 52d, 55d, and 58d in which the pressure is increased, the purge gas is supplied into the processing chamber 1 at a relatively high flow rate, for example, at a flow rate higher than the flow rate of the carrier gas. Therefore, the TiCl₄ gas and the SiH₄ gas remaining in the processing chamber 1 are quickly discharged to the exhaust pipe 41, and the TiCl₄ and SiH₄ gas atmosphere is replaced with the N₂ gas atmosphere in the processing chamber 1 in a short period of time.

Further, because the valve 51e is closed, the TiCl₄ gas supplied from the first source gas supply source 51a to the gas supply line 51b is stored in the storage tank 51d, and the pressure in the storage tank 51d is increased. Further, because the valve 54e is closed, the SiH₄ gas supplied from the second source gas supply source 54a to the gas supply line 54b is stored in the storage tank 54d, and the pressure in the storage tank 54d is increased.

After a predetermined processing time (for example, 0.01 seconds to 5 seconds) has elapsed after the valves 52e, 55e, and 58e are opened, the controller 6 closes the valves 52e, 55e, and 58e.

In step S104, NH₃ gas (reaction gas) is supplied into the processing chamber 1. In this step, the controller 6 opens the valve 57e. Thus, NH₃ gas stored in the storage tank 57d is supplied into the processing chamber 1. The first source gas (TiCl₄) and the second source gas (SiH₄) adsorbed on the substrate W react with the reaction gas (NH₃), and as a result, a TiSiN film is formed.

Further, concurrently with the supply of the NH₃ gas into the processing chamber 1, the purge gas (N₂ gas) is supplied from the N₂ gas supply sources 52a, 55a, and 58a to the gas supply lines 52b, 55b, and 58b. At this time, the valves 52e, 55e, and 58e are closed. Thus, the purge gas is stored in the storage tanks 52d, 55d, and 58d, and the pressure in the storage tanks 52d, 55d, and 58d is increased.

After a predetermined processing time (for example, 0.01 seconds to 5 seconds) has elapsed after the valve 57e is opened, the controller 6 closes the valve 57e.

In step S105, the purge gas is supplied into the processing chamber 1 to purge the gas in the processing chamber 1. In this step, the controller 6 opens the valves 52e, 55e, and 58e. Thus, the purge gas stored in each of the storage tanks 52d, 55d, and 58d is supplied into the processing chamber 1. At this time, because the purge gas is supplied from the storage tanks 52d, 55d, and 58d in which the pressure is increased, the purge gas is supplied into the processing chamber 1 at a relatively high flow rate, for example, at a flow rate higher than the flow rate of the carrier gas. Therefore, the NH₃ gas remaining in the processing chamber 1 is quickly discharged to the exhaust pipe 41, and the NH₃ gas atmosphere is replaced with the N₂ gas atmosphere in the processing chamber 1 in a short period of time.

Further, because the valve 57e is closed, the NH₃ gas supplied from the reaction gas supply source 57a to the gas supply line 57b is stored in the storage tank 57d, and the pressure in the storage tank 57d is increased.

After a predetermined processing time (for example, 0.01 seconds to 5 seconds) has elapsed after the valves 52e, 55e, and 58e are opened, the controller 6 closes the valves 52e, 55e, and 58e.

In step S106, the controller 6 determines whether the number of repetitions z of the processing from step S102 to step S105 has reached a predetermined number of times. If the processing has not been repeated the predetermined number of times (NO in step S106), the controller 6 causes the film forming process to return to S102. If the processing has been repeated the predetermined number of times (YES in step S106), the controller 6 ends the film forming process. By repeating the processing from step S102 to step S105 the predetermined number of times, a TiSiN film having a desired thickness is formed on the substrate W.

Thereafter, the substrate W is unloaded from the processing chamber 1 in the reverse order of the procedure performed at the time of loading the substrate W into the processing chamber 1.

In the above-described example, in steps S103 and S105, an example in which the purge gas (N₂ gas) stored in the storage tanks 52d, 55d, and 58d is supplied into the processing chamber 1 to purge the processing chamber 1 has been described, but the present disclosure is not limited thereto. For example, instead of supplying the purge gas (N₂ gas) stored in the storage tanks 52d, 55d, and 58d into the processing chamber 1, the carrier gas (N₂ gas) may be supplied from the N₂ gas supply sources 53a, 56a, and 59a into the processing chamber 1 to purge the processing chamber 1.

### Gas Supply Timing Adjustment Mechanism According to First Embodiment

Next, an example of the gas supply timing adjustment mechanism 7 of the film forming apparatus according to the first embodiment will be described with reference to FIG. 4. FIG. 4 is an example of a configuration diagram of the gas supply timing adjustment mechanism 7 of the film forming apparatus according to the first embodiment. In step S102 (see FIG. 2), the gas supply timing adjustment mechanism 7 simultaneously supplies the first source gas (TiCl₄ gas) and the second source gas (SiH₄ gas) into the processing chamber 1.

The gas supply line for supplying the first source gas from the first source gas supply source 51a into the processing chamber 1 and the gas supply line for supplying the second source gas from the second source gas supply source 54a into the processing chamber 1 are illustrated in FIG. 4, and will be described. Further, the gas supply lines (see FIG. 1) for supplying the purge gas, the carrier gas, and the reaction gas are not illustrated in FIG. 4, and a description thereof will be omitted. In FIG. 4, the gas supply lines for supplying process gases (the first source gas and the second source gas) are indicated by solid lines, pneumatic supply lines for supplying compressed air pressure are indicated by dashed lines, and a control signal is indicated by a dash-dot line.

The gas supply timing adjustment mechanism 7 includes the flow rate controller 51c, the flow rate controller 54c, the storage tank 51d (a first storage tank), the storage tank 54d (a second storage tank), the valve 51e (a first opening and closing valve), the valve 54e (a second opening and closing valve), and a solenoid valve 71 (a first solenoid valve).

The storage tank 51d is provided in the gas supply line 51b (a first gas supply line) for supplying the first source gas from the first source gas supply source 51a to the processing chamber 1, and stores the first source gas. The storage tank 54d is provided in the gas supply line 54b (a second gas supply line) for supplying the second source gas from the second source gas supply source 54a to the processing chamber 1, and stores the second source gas. The flow rate controller 51c is, for example, a mass flow controller. The flow rate controller 51c is provided in the gas supply line 51b upstream of the storage tank 51d, and adjusts the flow rate of the first source gas supplied from the first source gas supply source 51a to the storage tank 51d. The flow rate controller 54c is, for example, a mass flow controller. The flow rate controller 54c is provided in the gas supply line 54b upstream of the storage tank 54d, and adjusts the flow rate of the second source gas supplied from the second source gas supply source 54a to the storage tank 54d.

The valve 51e is an opening and closing valve provided in the gas supply line 51b between the storage tank 51d and the processing chamber 1. The valve 54e is an opening and closing valve provided in the gas supply line 54b between the storage tank 54d and the processing chamber 1. The valves 51e and 54e are air-operated valves that are opened and closed in response to the supply of compressed air pressure. Further, the valves 51e and 54e are normally-closed valves, and are closed when no compressed air pressure is supplied to pilot ports thereof and are opened when compressed air pressure is supplied to the pilot ports thereof.

An air supply source 70 supplies compressed air. Pneumatic supply line 75a, 75c1, and 75c2 supply compressed air pressure from the air supply source 70 to the pilot ports of the valves 51e and 54e. One end of the pneumatic supply line 75a is connected to the air supply source 70, and the other end of the pneumatic supply line 75a is connected to a branch part 75b. The other end of the pneumatic supply line 75a, one end of the pneumatic supply line 75c1, and one end of the pneumatic supply line 75c2 are connected to the branch part 75b. That is, the branch part 75b branches the pneumatic supply line 75a into the pneumatic supply line 75c1 and the pneumatic supply line 75c2. The other end of the pneumatic supply line 75c1 is connected to the pilot port of the valve 51e. The other end of the pneumatic supply line 75c2 is connected to the pilot port of the valve 54e.

The solenoid valve 71 is an opening and closing valve provided in the pneumatic supply line 75a upstream of the branch part 75b. The solenoid valve 71 is a solenoid valve that is opened and closed by a control signal from the controller 6. The solenoid valve 71 is a normally-closed valve, and is closed when no control signal is supplied and is opened when a control signal is supplied.

The controller 6 controls the gas supply timing adjustment mechanism 7. Specifically, the controller 6 controls the opening and closing of the solenoid valve 71.

In response to the controller 6 outputting a control signal instructing the solenoid valve 71 to be opened, the solenoid valve 71 is opened. When the solenoid valve 71 is opened, compressed air pressure supplied from the air supply source 70 is simultaneously supplied to the pilot ports of the valves 51e and 54e. By simultaneously supplying the compressed air pressure to the pilot ports of the valves 51e and 54e, the valves 51e and 54e are simultaneously opened, and the first source gas (TiCl₄ gas) and the second source gas (SiH₄ gas) are simultaneously supplied to the processing chamber 1.

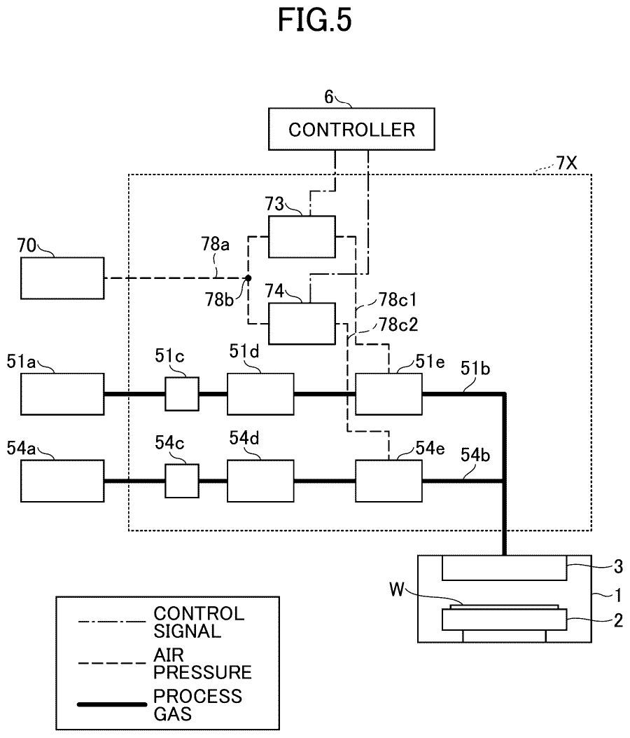

An example of a gas supply timing adjustment mechanism 7X according to a reference example will be described with reference to FIG. 5. FIG. 5 is an example of a configuration diagram of the gas supply timing adjustment mechanism 7X of a film forming apparatus according to the reference example.

A gas supply line for supplying a first source gas from a first source gas supply source 51a to a processing chamber 1 and a gas supply line for supplying a second source gas from a second source gas supply source 54a to the processing chamber 1 are illustrated in FIG. 5, and will be described. Further, gas supply lines for supplying a purge gas, a carrier gas, and a reaction gas (as in FIG. 1) are not illustrated in FIG. 5, and a description thereof will be omitted. Further, in FIG. 5, the gas supply lines for supplying process gases (the first source gas and the second source gas) are indicated by solid lines, pneumatic supply lines for supplying compressed air pressure are indicated by dashed lines, and control signals are indicated by dash-dot lines.

The gas supply timing adjustment mechanism 7X includes a flow rate controller 51c, a flow rate controller 54c, a storage tank 51d, a storage tank 54d, a valve 51e, a valve 54e, a solenoid valve 73, and a solenoid valve 74.

The storage tank 51d is provided in a gas supply line 51b for supplying the first source gas from the first source gas supply source 51a to the processing chamber 1, and stores the first source gas. The storage tank 54d is provided in a gas supply line 54b for supplying the second source gas from the second source gas supply source 54a to the processing chamber 1, and stores the second source gas. The flow rate controller 51c is, for example, a mass flow controller. The flow rate controller 51c is provided in the gas supply line 51b upstream of the storage tank 51d, and adjusts the flow rate of the first source gas supplied from the first source gas supply source 51a to the storage tank 51d. The flow rate controller 54c is, for example, a mass flow controller. The flow rate controller 54c is provided in the gas supply line 54b upstream of the storage tank 54d, and adjusts the flow rate of the second source gas supplied from the second source gas supply source 54a to the storage tank 54d.

The valve 51e is an opening and closing valve provided in the gas supply line 51b between the storage tank 51d and the processing chamber 1. The valve 54e is an opening and closing valve provided in the gas supply line 54b between the storage tank 54d and the processing chamber 1. The valves 51e and 54e are air-operated valves that are opened and closed in response to the supply of compressed air pressure. Further, the valves 51e and 54e are normally-closed valves, and are closed when no compressed air pressure is supplied to pilot ports thereof and are opened when compressed air pressure is supplied to the pilot ports thereof.

An air supply source 70 supplies compressed air. Pneumatic supply line 78a, 78c1, and 78c2 supply compressed air pressure from the air supply source 70 to the pilot ports of the valves 51e and 54e. One end of the pneumatic supply line 78a is connected to the air supply source 70, and the other end of the pneumatic supply line 78a is connected to a branch part 78b. The other end of the pneumatic supply line 78a, one end of the pneumatic supply line 78c1, and one end of the pneumatic supply line 78c2 are connected to the branch part 78b. That is, the branch part 78b branches the pneumatic supply line 78a into the pneumatic supply line 78c1 and the pneumatic supply line 78c2. The other end of the pneumatic supply line 78c1 is connected to the pilot port of the valve 51e. The other end of the pneumatic supply line 78c2 is connected to the pilot port of the valve 54e.

The solenoid valve 73 is an opening and closing valve provided in the pneumatic supply line 78c1 downstream of the branch part 78b. The solenoid valve 74 is an opening and closing valve provided in the pneumatic supply line 78c2 downstream of the branch part 78b. The solenoid valves 73 and 74 are solenoid valves that are opened and closed by control signals from the controller 6. Further, the solenoid valves 73 and 74 are normally-closed valves, and are closed when no control signals are supplied and are opened when control signals are supplied.

The controller 6 controls the gas supply timing adjustment mechanism 7X. Specifically, the controller 6 controls the opening and closing of the solenoid valves 73 and 74.

In response to the controller 6 outputting a control signal instructing the solenoid valve 73 to be opened, the solenoid valve 73 is opened. When the solenoid valve 73 is opened, compressed air pressure supplied from the air supply source 70 is supplied to the pilot port of the valve 51e. By supplying the compressed air pressure to the pilot port of valve 51e, the valve 51e is opened, and the first source gas (TiCl₄ gas) is supplied to the processing chamber 1.

Further, in response to the controller 6 outputting a control signal instructing the solenoid valve 74 to be opened, the solenoid valve 74 is opened. When the solenoid valve 74 is opened, compressed air pressure supplied from the air supply source 70 is supplied to the pilot port of the valve 54e. By supplying the compressed air pressure to the pilot port of valve 54e, the valve 54e is opened, and the second source gas (SiH₄ gas) is supplied to the processing chamber 1.

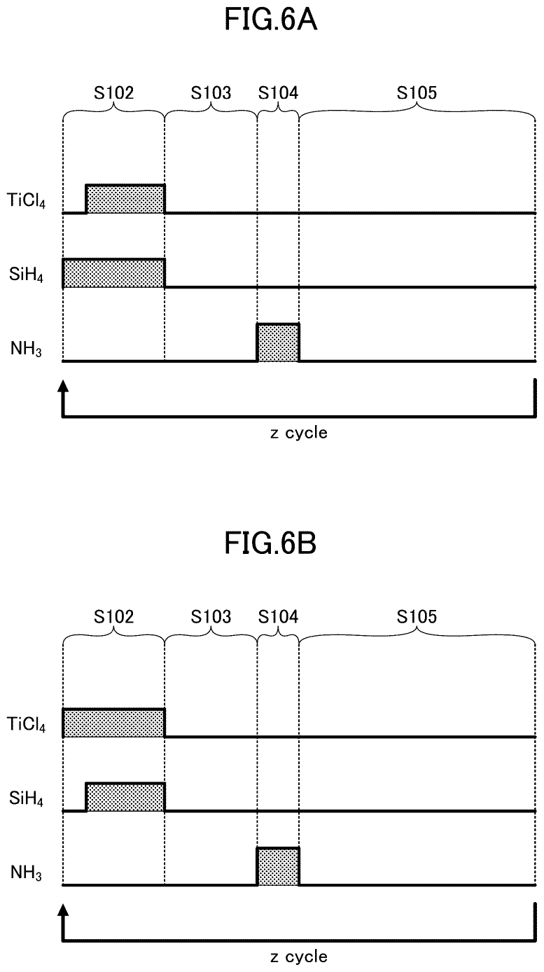

FIGS. 6A and 6B are time charts illustrating examples of timings of gas supply in a film forming method according to the reference example.

In the gas supply timing adjustment mechanism 7X of the film forming apparatus according to the reference example, the solenoid valve 73 for controlling the opening and closing of the valve 51e and the solenoid valve 74 for controlling the opening and closing of the valve 54e are separately provided. Therefore, even when the controller 6 simultaneously outputs control signals for instructing the solenoid valves 73 and 74 to be opened in step S102, there is a possibility that a timing difference occurs between the start of the supply of the first source gas (TiCl₄ gas) and the start of supply of the second source gas (SiH₄ gas) due to machine-to-machine variations and the like.

FIG. 6A is a time chart illustrating an example of timings of gas supply when the valve 51e is opened later than the valve 54e.

In this example, in step S102, the adsorption of the second source gas (SiH₄ gas) is started first and the adsorption of the first source gas (TiCl₄ gas) is started later. Thus, the adsorption amount of SiH₄ adsorbed on the surface of the substrate W increases and the adsorption amount of TiCl₄ adsorbed on the surface of the substrate W decreases. Therefore, in a TiSiN film formed on the substrate W, the atomic concentration of Si increases and the atomic concentration of Ti decreases.

FIG. 6B is a time chart illustrating an example of timings of gas supply when the valve 54e is opened later than the valve 51e.

In this example, in step S102, the adsorption of the first source gas (TiCl₄ gas) is started first and the adsorption of the second source gas (SiH₄ gas) is started later. Thus, the adsorption amount of TiCl₄ adsorbed on the surface of the substrate W increases and the adsorption amount of SiH₄ adsorbed on the surface of the substrate W decreases. Therefore, in a TiSiN film formed on the substrate W, the atomic concentration of Ti increases and the atomic concentration of Si decreases.

As described above, in the gas supply timing adjustment mechanism 7X (see FIG. 5) of the film forming apparatus according to the reference example, the quality of a TiSiN film formed on the substrate W is likely to be unstable due to machine-to-machine variations and the like. For example, the atomic concentrations of Ti and Si in a TiSiN film formed on the substrate W is likely to be unstable.

Conversely, in the gas supply timing adjustment mechanism 7 (see FIG. 4) of the film forming apparatus according to the first embodiment, the controller 6 outputs a control signal instructing one solenoid valve 71 to be opened. When the solenoid valve 71 is opened, the compressed air pressure is simultaneously supplied to the pilot port of the valve 51e and the pilot port of the valve 54e, and the valves 51e and 54e are simultaneously opened. That is, a timing difference between the start of supply of the first source gas (TiCl₄ gas) and the start of supply of the second source gas (SiH₄ gas) can be reduced. Alternatively, in the gas supply timing adjustment mechanism 7 (see FIG. 4) of the film forming apparatus according to the first embodiment, a timing at which the supply of the first source gas (TiCl₄ gas) is started can coincide with a timing at which the supply of the second source gas (SiH₄ gas) is started (see FIG. 3). Accordingly, the quality of a TiSiN film formed on the substrate W can be stabilized. For example, the atomic concentrations of Ti and Si in a TiSiN film formed on the substrate W can be stabilized.

By adjusting the flow rate of the first source gas (TiCl₄ gas) supplied from the storage tank 51d to the processing chamber 1 as controlled by the flow rate controller 51c and the flow rate of the second source gas (SiH₄ gas) supplied from the storage tank 54d to the processing chamber 1 as controlled by the flow rate controller 54c, the atomic concentrations of Ti and Si in a TiSiN film formed on the substrate W can be adjusted, and the quality of the TiSiN film can be adjusted.

### Gas Supply Timing Adjustment Mechanism According to Second Embodiment

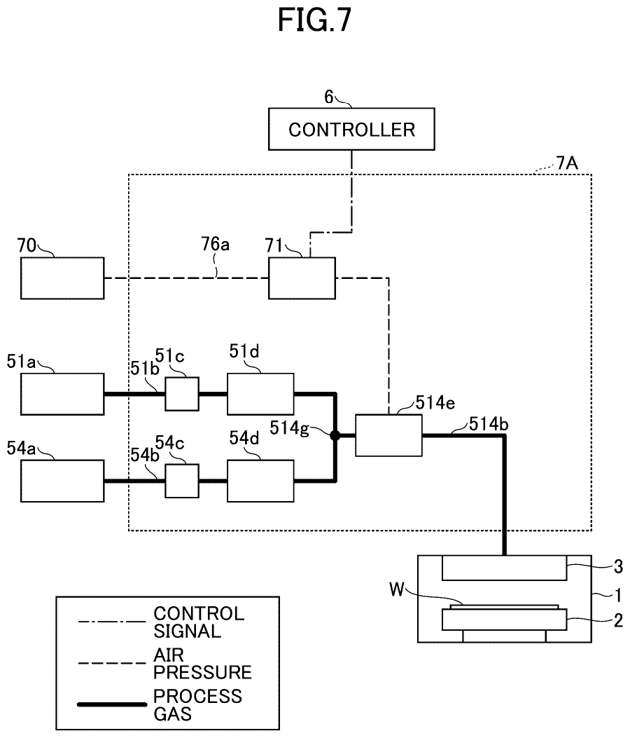

Next, an example of a gas supply timing adjustment mechanism 7A of a film forming apparatus according to a second embodiment will be described with reference to FIG. 7. FIG. 7 is an example of a configuration diagram of the gas supply timing adjustment mechanism 7A of the film forming apparatus according to the second embodiment. In step S102 (see FIG. 2), the gas supply timing adjustment mechanism 7A simultaneously supplies the first source gas (TiCl₄ gas) and the second source gas (SiH₄ gas) to the processing chamber 1.

The film forming apparatus according to the second embodiment differs from the film forming apparatus according to the first embodiment (see FIG. 1) in a gas supply line for supplying the first source gas from a first source gas supply source 51a to the processing chamber 1 and a gas supply line for supplying the second source gas from a second source gas supply source 54a to the processing chamber 1. Other configurations are the same as those of the first embodiment, and a duplicate description thereof will be omitted. The gas supply line for supplying the first source gas from the first source gas supply source 51a to the processing chamber 1 and the gas supply line for supplying the second source gas from the second source gas supply source 54a to the processing chamber 1 are illustrated in FIG. 7, and will be described. Gas supply lines for supplying the purge gas, the carrier gas, and the reaction gas (see FIG. 1) are not illustrated in FIG. 7, and a description thereof will be omitted.

The gas supply timing adjustment mechanism 7A includes a flow rate controller 51c, a flow rate controller 54c, a storage tank 51d (a first storage tank), a storage tank 54d (a second storage tank), a valve 514e (an opening and closing valve), and a solenoid valve 71 (a first solenoid valve). One end of the gas supply line 51b is connected to the first source gas supply source 51a, and the other end of the gas supply line 51b is connected to a merging part 514g. One end of the gas supply line 54 b is connected to the second source gas supply source 54a, and the other end of the gas supply line 54b is connected to the merging part 514g. The other end of the gas supply line 51b, the other end of the gas supply line 54b, and one end of the gas supply line 514b are connected to the merging part 514g. That is, the merging part 514g merges the gas supply line 51b and the gas supply line 54b into the gas supply line 514b. The other end of the gas supply line 514b is connected to the showerhead 3.

The storage tank 51d is provided in the gas supply line 51b for supplying the first source gas from the first source gas supply source 51a to the processing chamber 1, and stores the first source gas. The storage tank 54d is provided in the gas supply line 54b for supplying the second source gas from the second source gas supply source 54a to the processing chamber 1, and stores the second source gas. The flow rate controller 51c is, for example, a mass flow controller. The flow rate controller 51c is provided in the gas supply line 51b upstream of the storage tank 51d, and adjusts the flow rate of the first source gas supplied from the first source gas supply source 51a to the storage tank 51d. The flow rate controller 54c is, for example, a mass flow controller. The flow rate controller 54c is provided in the gas supply line 54b upstream of the storage tank 54d, and adjusts the flow rate of the second source gas supplied from the second source gas supply source 54a to the storage tank 54d.

The valve 514e is an opening and closing valve provided in the gas supply line 514b downstream of the merging part 514g. The gas supply line 514 b is a gas supply line between the processing chamber 1 and the storage tanks 51d and 54d. The valve 514e is an air-operated valve that is opened and closed in response to the supply of compressed air pressure. Further, the valve 514e is a normally-closed valve, and is closed when no compressed air pressure is supplied to a pilot port thereof and is opened when compressed air pressure is supplied to the pilot port thereof.

An air supply source 70 supplies compressed air. A pneumatic supply line 76a supplies compressed air pressure from the air supply source 70 to the pilot port of the valve 514e. One end of the pneumatic supply line 76a is connected to the air supply source 70, and the other end of the pneumatic supply line 76a is connected to pilot port of the valve 514e.

The solenoid valve 71 is an opening and closing valve provided in the pneumatic supply line 76a. The solenoid valve 71 is a solenoid valve that is opened and closed by a control signal from the controller 6. Further, the solenoid valve 71 is a normally-closed valve, and is closed when no control signal is supplied and is opened when a control signal is supplied.

The controller 6 controls the gas supply timing adjustment mechanism 7A. Specifically, the controller 6 controls the opening and closing of the solenoid valve 71.

In response to the controller 6 outputting a control signal instructing the solenoid valve 71 to be opened, the solenoid valve 71 is opened. When the solenoid valve 71 is opened, compressed air pressure supplied from the air supply source 70 is supplied to the pilot port of the valve 514e. By supplying the compressed air pressure to the pilot port of valve 514e, the valve 514e is opened, and the first source gas (TiCl₄ gas) and the second source gas (SiH₄ gas) are simultaneously supplied to the processing chamber 1.

In the gas supply timing adjustment mechanism 7A (see FIG. 7) of the film forming apparatus according to the second embodiment, a timing at which the supply of the first source gas (TiCl₄ gas) is started can coincide with a timing at which the supply of the second source gas (SiH₄ gas) is started (see FIG. 3). Accordingly, the quality of a TiSiN film formed on the substrate W can be stabilized. For example, the atomic concentrations of Ti and Si in a TiSiN film formed on the substrate W can be stabilized.

By adjusting the flow rate of the first source gas (TiCl₄ gas) supplied from the storage tank 51d to the processing chamber 1 as controlled by the flow rate controller 51c and the flow rate of the second source gas (SiH₄ gas) supplied from the storage tank 54d to the processing chamber 1 as controlled by the flow rate controller 54c, the atomic concentrations of Ti and Si in a TiSiN film formed on the substrate W can be adjusted, and the quality of the TiSiN film can be adjusted.

### Gas Supply Timing Adjustment Mechanism According to Third Embodiment

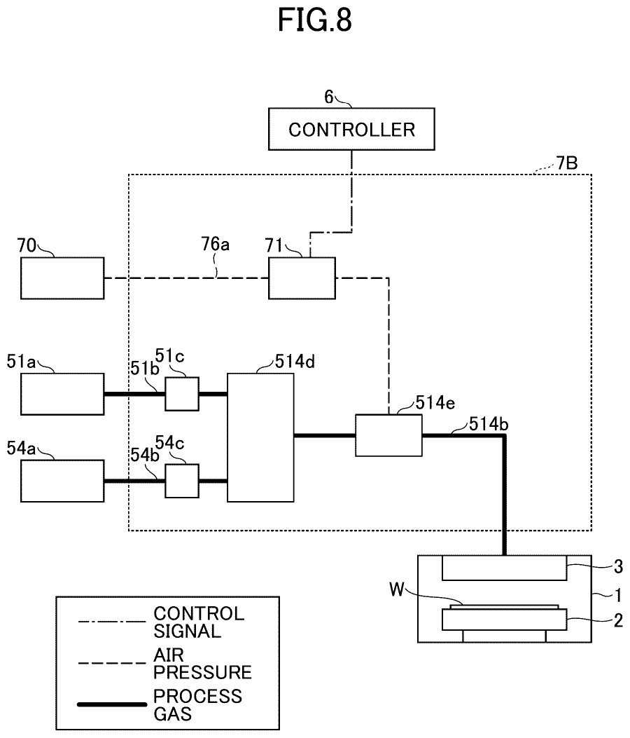

Next, an example of a gas supply timing adjustment mechanism 7B of a film forming apparatus according to a third embodiment will be described with reference to FIG. 8. FIG. 8 is an example of a configuration diagram of the gas supply timing adjustment mechanism 7B of the film forming apparatus according to the third embodiment. In step S102 (see FIG. 2), the gas supply timing adjustment mechanism 7B simultaneously supplies the first source gas (TiCl₄ gas) and the second source gas (SiH₄ gas) into the processing chamber 1.

The film forming apparatus according to the third embodiment differs from the film forming apparatus according to the first embodiment (see FIG. 1) in a gas supply line for supplying the first source gas from a first source gas supply source 51a to the processing chamber 1 and a gas supply line for supplying the second source gas from a second source gas supply source 54a to the processing chamber 1. Other configurations are the same as those of the first embodiment, and a duplicate description thereof will be omitted. The gas supply line for supplying the first source gas from the first source gas supply source 51a to the processing chamber 1 and the gas supply line for supplying the second source gas from the second source gas supply source 54a to the processing chamber 1 are illustrated in FIG. 8, and will be described. Gas supply lines for supplying the purge gas, the carrier gas, and the reaction gas (see FIG. 1) are not illustrated in FIG. 8, and a description thereof will be omitted.

The gas supply timing adjustment mechanism 7B includes a flow rate controller 51c, a flow rate controller 54c, a storage tank 514d (a first storage tank), a valve 514e (a first opening and closing valve), and a solenoid valve 71 (a first solenoid valve). One end of the gas supply line 51b is connected to the first source gas supply source 51a, and the other end of the gas supply line 51b is connected to the storage tank 514d. One end of the gas supply line 54b is connected to the second source gas supply source 54a, and the other end of the gas supply line 54b is connected to the storage tank 514d. One end of a gas supply line 514b is connected to the storage tank 514d, and the other end of the gas supply line 514b is connected to the showerhead 3.

The storage tank 514d is supplied with the first source gas from the first source gas supply source 51a via the gas supply line 51b, is supplied with the second source gas from the second source gas supply source 54a via the gas supply line 54b, and stores the first source gas and the second source gas. The flow rate controller 51c is, for example, a mass flow controller. The flow rate controller 51c is provided in the gas supply line 51b upstream of the storage tank 514d, and adjusts the flow rate of the first source gas supplied from the first source gas supply source 51a to the storage tank 514d. The flow rate controller 54c is, for example, a mass flow controller. The flow rate controller 54c is provided in the gas supply line 54b upstream of the storage tank 514d, and adjusts the flow rate of the second source gas supplied from the second source gas supply source 54a to the storage tank 514d.

The valve 514e is an opening and closing valve provided in the gas supply line 514b between the storage tank 514d and the processing chamber 1. The valve 514e is an air-operated valve that is opened and closed in response to the supply of compressed air pressure. Further, the valve 514e is a normally-closed valve, and is closed when no compressed air pressure is supplied to a pilot port thereof and is opened when compressed air pressure is supplied to the pilot port thereof.

An air supply source 70 supplies compressed air. A pneumatic supply line 76a supplies compressed air pressure from the air supply source 70 to the pilot port of the valve 514e. One end of the pneumatic supply line 76a is connected to the air supply source 70, and the other end of the pneumatic supply line 76a is connected to the pilot port of the valve 514e.

The solenoid valve 71 is an opening and closing valve provided in the pneumatic supply line 76a. The solenoid valve 71 is a solenoid valve that is opened and closed by a control signal from the controller 6. Further, the solenoid valve 71 is a normally-closed valve, and is closed when no control signal is supplied and is opened when a control signal is supplied.

The controller 6 controls the gas supply timing adjustment mechanism 7B. Specifically, the controller 6 controls the opening and closing of the solenoid valve 71.

In response to the controller 6 outputting a control signal instructing the solenoid valve 71 to be opened, the solenoid valve 71 is opened. When the solenoid valve 71 is opened, compressed air pressure supplied from the air supply source 70 is supplied to the pilot port of the valve 514e. By supplying the compressed air pressure to the pilot port of valve 514e, the valve 514e is opened, and the first source gas (TiCl₄ gas) and the second source gas (SiH₄ gas) are simultaneously supplied into the processing chamber 1.

In the gas supply timing adjustment mechanism 7B (see FIG. 8) of the film forming apparatus according to the third embodiment, a timing at which the supply of the first source gas (TiCl₄ gas) is started can coincide with a timing at which the supply of the second source gas (SiH₄ gas) is started (see FIG. 3). Accordingly, the quality of a TiSiN film formed on the substrate W can be stabilized. For example, the atomic concentrations of Ti and Si in a TiSiN film formed on the substrate W can be stabilized.

By adjusting the flow rate of the first source gas (TiCl₄ gas) supplied from the storage tank 51d to the processing chamber 1 as controlled by the flow rate controller 51c and the flow rate of the second source gas (SiH₄ gas) supplied from the storage tank 54d to the processing chamber 1 as controlled by the flow rate controller 54c, the partial pressure of the first source gas (TiCl₄ gas) and the partial pressure of the second source gas (SiH₄ gas) stored in the storage tank 514d are adjusted. By adjusting the partial pressure of the first source gas (TiCl₄ gas) and the partial pressure of the second source gas (SiH₄ gas) stored in the storage tank 514d, the atomic concentrations of Ti and Si in a TiSiN film formed on the substrate W can be adjusted, and the quality of the TiSiN film can be adjusted.

### Gas Supply Timing Adjustment Mechanism According to Fourth Embodiment

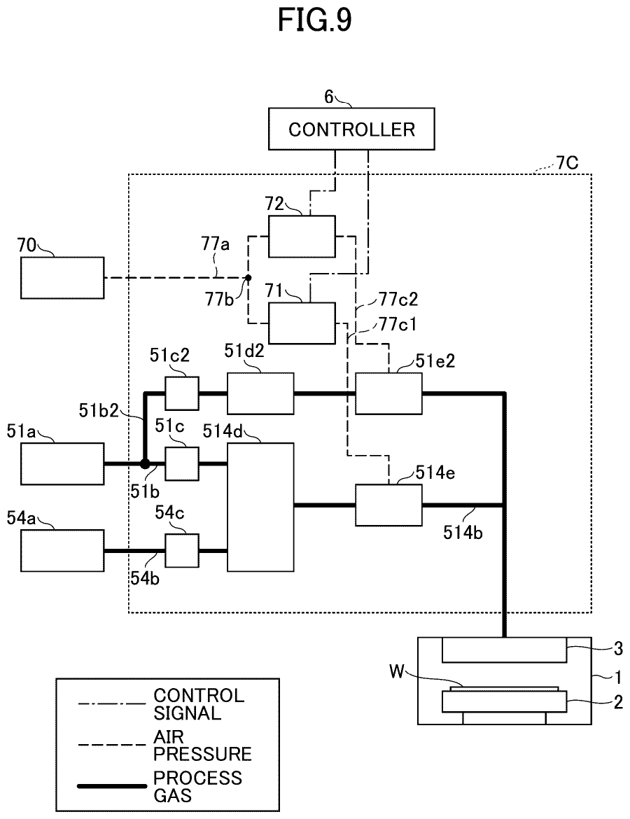

Next, an example of a gas supply timing adjustment mechanism 7C of a film forming apparatus according to a fourth embodiment will be described with reference to FIG. 9. FIG. 9 is an example of a configuration diagram of the gas supply timing adjustment mechanism 7C of the film forming apparatus according to the fourth embodiment. In step S102 (see FIG. 2), the gas supply timing adjustment mechanism 7C simultaneously supplies the first source gas (TiCl₄ gas) and the second source gas (SiH₄ gas) into the processing chamber 1.

The film forming apparatus according to the fourth embodiment differs from the film forming apparatus according to the first embodiment (see FIG. 1) in a gas supply line for supplying the first source gas from a first source gas supply source 51a to the processing chamber 1 and a gas supply line for supplying the second source gas from a second source gas supply source 54a to the processing chamber 1. Other configurations are the same as those of the first embodiment, and a duplicate description thereof will be omitted. The gas supply line for supplying the first source gas from the first source gas supply source 51a to the processing chamber 1 and the gas supply line for supplying the second source gas from the second source gas supply source 54a to the processing chamber 1 are illustrated in FIG. 9, and will be described. Gas supply lines for supplying the purge gas, the carrier gas, and the reaction gas (see FIG. 1) are not illustrated in FIG. 9, and a description thereof will be omitted.

The gas supply timing adjustment mechanism 7C includes a flow rate controller 51c, a flow rate controller 54c, a flow rate controller 51c2, a storage tank 514d (a first storage tank), a storage tank 51d2 (a second storage tank), a valve 514e (a first opening and closing valve), a valve 51e2 (a second opening and closing valve), a solenoid valve 71 (a first solenoid valve), and a solenoid valve 72 (a second solenoid valve). One end of the gas supply line 51b is connected to the first source gas supply source 51a, and the other end of the gas supply line 51b is connected to the storage tank 514d. One end of the gas supply line 54b is connected to the second source gas supply source 54a, and the other end of the gas supply line 54b is connected to the storage tank 514d. One end of a gas supply line 514b is connected to the storage tank 514d, and the other end of the gas supply line 514b is connected to the showerhead 3. In addition, one end of a gas supply line 51b2 branches from the gas supply line 51b, and the other end of the gas supply line 51b2 merges with the gas the supply line 514b downstream of the valve 514e and is connected to the showerhead 3. The gas supply line 51b2 is provided with the flow rate controller 51c2, the storage tank 51d2, and the valve 51e2 in this order from the upstream side.

The storage tank 514d is supplied with the first source gas from the first source gas supply source 51a via the gas supply line 51b, is supplied with the second source gas from the second source gas supply source 54a via the gas supply line 54b, and stores the first source gas and the second source gas. The flow rate controller 51c is, for example, a mass flow controller. The flow rate controller 51c is provided in the gas supply line 51b downstream of a branch part between the gas supply line 51b and the gas supply line 51b2 and upstream of the storage tank 514d, and adjusts the flow rate of the first source gas supplied from the first source gas supply source 51a to the storage tank 514d. The flow rate controller 54c is, for example, a mass flow controller. The flow rate controller 54c is provided in the gas supply line 54b upstream of the storage tank 514d, and adjusts the flow rate of the second source gas supplied from the second source gas supply source 54a to the storage tank 514d.

The storage tank 51d2 is provided in the gas supply line 51b2 for supplying the first source gas from the first source gas supply source 51a to the processing chamber 1, and stores the first source gas. The flow rate controller 51c2 is, for example, a mass flow controller. The flow rate controller 51c2 is provided in the gas supply line 51b2 downstream of the branch part between the gas supply line 51b and the gas supply line 51b2 and upstream of the storage tank 51d2, and adjusts the flow rate of the first source gas supplied from the first source gas supply source 51a to the storage tank 51d2.

The valve 514e is an opening and closing valve provided in the gas supply line 514b between the storage tank 514d and the processing chamber 1. The valve 51e2 is an opening and closing valve provided in the gas supply line 51b2 between the storage tank 51d2 and the processing chamber 1. The valves 514e and 51e2 are air-operated valves that are opened and closed in response to the supply of compressed air pressure. Further, the valves 514e and 51e2 are normally-closed valves, and are closed when no compressed air pressure is supplied to pilot ports thereof and are opened when compressed air pressure is supplied to the pilot ports thereof.

An air supply source 70 supplies compressed air. Pneumatic supply lines 77a, 77c1, and 77c2 supply compressed air pressure from the air supply source 70 to the pilot ports of the valves 514e and 51e2. One end of the pneumatic supply line 77a is connected to the air supply source 70, and the other end of the pneumatic supply line 77a is connected to a branch part 77b. The other end of the pneumatic supply line 77a, one end of the pneumatic supply line 77c1, and one end of the pneumatic supply line 77c2 are connected to the branch part 77b. That is, the branch part 77b branches the pneumatic supply line 77a into the pneumatic supply line 77c1 and the pneumatic supply line 77c2 . The other end of the pneumatic supply line 77c1 is connected to the pilot port of the valve 514e. The other end of the pneumatic supply line 77c2 is connected to the pilot port of the valve 51e2.

The solenoid valve 71 is an opening and closing valve provided in the pneumatic supply line 77c1 (a first pneumatic supply line). The solenoid valve 72 is an opening and closing valve provided in the pneumatic supply line 77c2 (a second pneumatic supply line). Each of the solenoid valves 71 and 72 is a solenoid valve that is opened/closed by a control signal from the controller 6. Further, each of the solenoid valve 71 and 72 is a normally-closed valve, and is closed when no control signal is supplied and is opened when a control signal is supplied.

The controller 6 controls the gas supply timing adjustment mechanism 7C. Specifically, the controller 6 controls the opening and closing of the solenoid valves 71 and 72.

In response to the controller 6 outputting a control signal instructing the solenoid valve 71 to be opened, the solenoid valve 71 is opened. When the solenoid valve 71 is opened, compressed air pressure supplied from the air supply source 70 is supplied to the pilot port of the valve 514e. By supplying the compressed air pressure to the pilot port of valve 514e, the valve 514e is opened, and the first source gas (TiCl₄ gas) and the second source gas (SiH₄ gas) are simultaneously supplied into the processing chamber 1.

Further, in response to the controller 6 outputting a control signal instructing the solenoid valve 72 to be opened, the solenoid valve 72 is opened. When the solenoid valve 72 is opened, compressed air pressure supplied from the air supply source 70 is supplied to the pilot port of the valve 51e2. By supplying the compressed air pressure to the pilot port of valve 51e2, the valve 51e2 is opened, and only the first source gas (TiCl₄ gas) is supplied into the processing chamber 1.

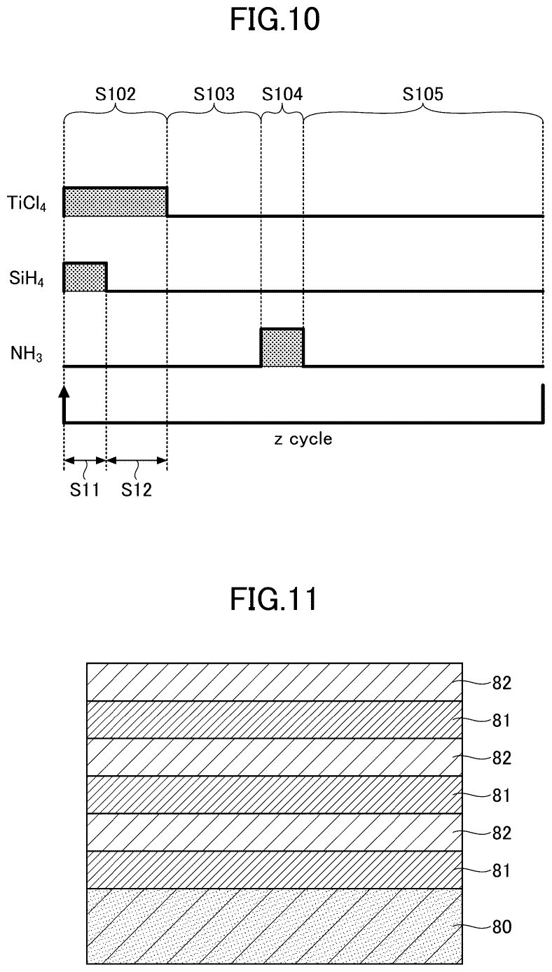

In the gas supply timing adjustment mechanism 7C of the film forming apparatus according to the fourth embodiment, in response to the controller 6 outputting a control signal instructing the solenoid valve 71 to be opened, the solenoid valve 71 is opened, and the valve 514e is opened. As a result, the first source gas (TiCl₄ gas) and the second source gas (SiH₄ gas) are simultaneously supplied into the processing chamber 1. That is, a timing at which the supply of the first source gas (TiCl₄ gas) is started can coincide with a timing at which the supply of the second source gas (SiH₄ gas) is started (see FIG. 10). Accordingly, the quality of a TiSiN film formed on the substrate W can be stabilized. For example, the atomic concentrations of Ti and Si in a TiSiN film formed on the substrate W can be stabilized.

By adjusting the flow rate of the first source gas (TiCl₄ gas) supplied from the storage tank 51d to the processing chamber 1 as controlled by the flow rate controller 51c and the flow rate of the second source gas (SiH₄ gas) supplied from the storage tank 54d to the processing chamber 1 as controlled by the flow rate controller 54c, the partial pressure of the first source gas (TiCl₄ gas) and the partial pressure of the second source gas (SiH₄ gas) stored in the storage tank 514d are adjusted. By adjusting the partial pressure of the first source gas (TiCl₄ gas) and the partial pressure of the second source gas (SiH₄ gas) stored in the storage tank 514d, the atomic concentrations of Ti and Si in a TiSiN film formed on the substrate W can be adjusted, and the quality of the TiSiN film can be adjusted.

Further, in the gas supply timing adjustment mechanism 7C of the film forming apparatus according to the fourth embodiment, in response to the controller 6 outputting a control signal instructing the solenoid valve 72 to be opened, the solenoid valve 72 is opened, and the valve 51e2 is opened. As a result, only the first source gas (TiCl₄ gas) is supplied into the processing chamber 1.

FIG. 10 is a time chart illustrating an example of timings of gas supply in a film forming method performed by the film forming apparatus according to the fourth embodiment.

The step (S102) of supplying the TiCl₄ gas (first source gas) and the SiH₄ gas (second source gas) into the processing chamber 1, the step (S103) of supplying the purge gas into the processing chamber 1, the step (S104) of supplying the NH3 gas (reaction gas) into the processing chamber 1, and the step (S105) of supplying the purge gas into the processing chamber 1 are repeated.

In this example, the step of supplying the TiCl₄ gas (first source gas) and the SiH₄ gas (second source gas) into the processing chamber 1 (see step S102 in FIG. 2) includes a step (S11) of simultaneously supplying the TiCl₄ gas (first source gas) and the SiH₄ gas (second source gas) and a step (S12) of supplying only the TiCl₄ gas (first source gas).

In step S11, the controller 6 outputs a control signal instructing the solenoid valve 71 to be opened. Thus, the solenoid valve 71 is opened, the valve 514e is opened, and the first source gas (TiCl₄ gas) and the second source gas (SiH₄ gas) are simultaneously supplied into the processing chamber 1.

In step S12, the controller 6 outputs a control signal instructing the solenoid valve 72 to be opened. Thus, the solenoid valve 72 is opened, the valve 51e2 is opened, and only the first source gas (TiCl₄ gas) is supplied into the processing chamber 1.

Accordingly, the first source gas (TiCl₄ gas) and the second source gas (SiH₄ gas) adsorbed on the substrate W can be adjusted. Thus, the atomic concentrations of Ti and Si in a TiSiN film formed on the substrate W can be adjusted, and the quality of the TiSiN film can be adjusted.

FIG. 11 is a schematic cross-sectional view illustrating an example of a film formed on the substrate W in another film forming method performed by the film forming apparatus according to the fourth embodiment.

In this example, a laminated film is formed by alternately repeating a step of forming a TiSiN film 81 and a step of forming a TiN film 82 on a substrate W including an underlying layer 80.

That is, in the step of forming the TiSiN film 81, the TiSiN film 81 is formed in accordance with the film forming method illustrated in FIG. 2. In step S102, the controller 6 outputs a control signal instructing the solenoid valve 71 to be opened. Thus, the solenoid valve 71 is opened, the valve 514e is opened, and the first source gas (TiCl₄ gas) and the second source gas (SiH₄ gas) are simultaneously supplied into the processing chamber 1. The other steps (S101 and S103 to S106) are the same as those described above, and thus a duplicate description thereof will be omitted.

Further, in the step of forming the TiN film 82, the TiN film 82 is formed by the ALD method as in the film forming method illustrated in FIG. 2. However, in step S102, the controller 6 outputs a control signal instructing the solenoid valve 72 to be opened. As a result, the solenoid valve 72 is opened, the valve 51e2 is opened, and only the first source gas (TiCl₄ gas) is supplied to the processing chamber 1. The other steps (S101 and S103 to S106) are the same as those described above, and thus a duplicate description thereof will be omitted.

Accordingly, the laminated film in which the TiSiN film 81 and the TiN film 82 are alternately laminated as illustrated in FIG. 11 can be formed by the film forming apparatus according to the fourth embodiment.

The gas supply timing adjustment mechanism 7C according to the fourth embodiment illustrated in FIG. 9 has a configuration in which only the first source gas (TiCl₄ gas) is supplied into the processing chamber 1, in addition to a configuration in which the first source gas (TiCl₄ gas) and the second source gas (SiH₄ gas) are simultaneously supplied into the processing chamber 1 as illustrated in the gas supply timing adjustment mechanism 7B according to the third embodiment illustrated FIG. 8. However, the present disclosure is not limited thereto.

### Gas Supply Timing Adjustment Mechanism According to Fifth Embodiment

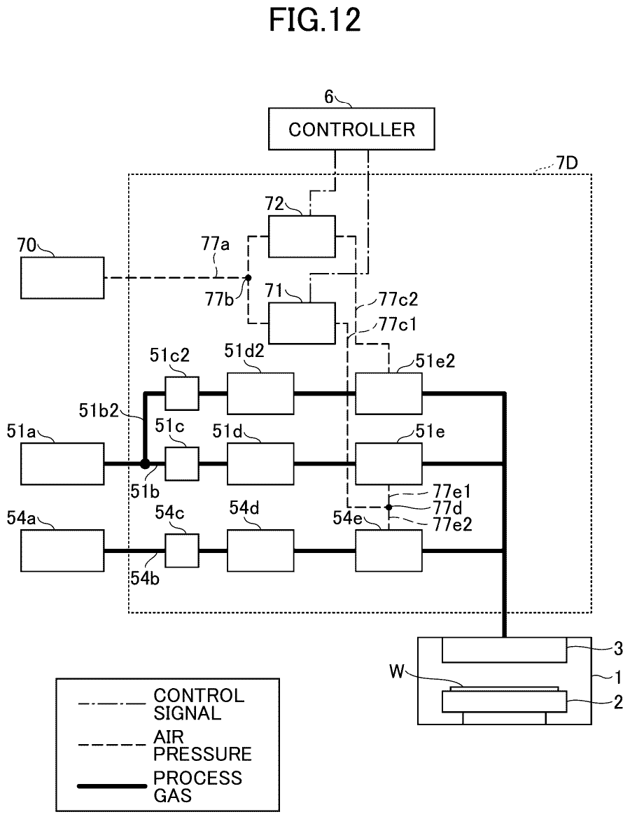

Next, an example of a gas supply timing adjustment mechanism 7D of a film forming apparatus according to a fifth embodiment will be described with reference to FIG. 12. FIG. 12 is an example of a configuration diagram of the gas supply timing adjustment mechanism 7D of the film forming apparatus according to the fifth embodiment.

The gas supply timing adjustment mechanism 7D according to the fifth embodiment illustrated in FIG. 12 has a configuration (including a gas supply line 51b2, a flow rate controller 51c2, a storage tank 51d2, a valve 51e2, a solenoid valve 72) in which only the first source gas (TiCl₄ gas) is supplied into the processing chamber 1, in addition to a configuration in which the first source gas (TiCl₄ gas) and the second source gas (SiH₄ gas) are simultaneously supplied into the processing chamber 1 as illustrated in the gas supply timing adjustment mechanism 7 according to the first embodiment illustrated in FIG. 4.

Specifically, one end of the gas supply line 51b2 branches from a gas supply line 51b upstream of a flow rate controller 51c, and the other end of the gas supply line 51b2 merges with the gas supply line 51b (or a gas supply line 54b downstream of a valve 54e) downstream of a valve 51e and is connected to the showerhead 3. The gas supply line 51b2 is provided with the flow rate controller 51c2, the storage tank 51d2 (a third storage tank), and the valve 51e2 (a third opening and closing valve) in this order from the upstream side.

The flow rate controller 51c2, the storage tank 51d2 , and the valve 51e2 provided in the gas supply line 51b2 are the same as the flow rate controller 51c2, the storage tank 51d2, and the valve 51e2 provided in the gas supply line 51b2 of the gas supply timing adjustment mechanism 7C according to the fourth embodiment (see FIG. 9), and thus a duplicate description thereof will be omitted.

Pneumatic supply lines 77a, 77c1, 77c2, 77e1, and 77e2 supply compressed air pressure from an air supply source 70 to pilot ports of the valves 51e, 54e and 51e2. One end of the pneumatic supply line 77a is connected to the air supply source 70 and the other end of the pneumatic supply line 77a is connected to a branch part 77b. The other end of the pneumatic supply line 77a, one end of the pneumatic supply line 77c1, and one end of the pneumatic supply line 77c2 are connected to the branch part 77b. That is, the branch part 77b branches the pneumatic supply line 77a into the pneumatic supply line 77c1 and the pneumatic supply line 77c2. The other end of the pneumatic supply line 77c1 is connected to a branch part 77d. The other end of the pneumatic supply line 77c2 is connected to the pilot port of the valve 51e2. The other end of the pneumatic supply line 77c1, one end of the pneumatic supply line 77e1, and one end of the pneumatic supply line 77e2 are connected to the branch part 77d. That is, the branch part 77d branches the pneumatic supply line 77c1 into the pneumatic supply line 77e1 and the pneumatic supply line 77e2. The other end of the pneumatic supply line 77e1 is connected to the pilot port of the valve 51e. The other end of the pneumatic supply line 77e2 is connected to the pilot port of the valve 54e.

A solenoid valve 71 is an opening and closing valve provided in the pneumatic supply line 77c1 (a first pneumatic supply line) upstream of the branch part 77d. A solenoid valve 72 is an opening and closing valve provided in the pneumatic supply line 77c2 (a second pneumatic supply line).

When the solenoid valve 71 is opened, compressed air is supplied to the valve 51e and the valve 54e. When the solenoid valve 72 is opened, compressed air is supplied to the valve 51e2.

According to the gas supply timing adjustment mechanism 7D according to the fifth embodiment, similar to the gas supply timing adjustment mechanism 7C according to the fourth embodiment, the step of simultaneously supplying the first source gas (TiCl₄ gas) and the second source gas (SiH₄ gas) into the processing chamber 1 and the step of supplying only the first source gas (TiCl₄ gas) into the processing chamber 1 can be performed.

### Gas Supply Timing Adjustment Mechanism According to Sixth Embodiment

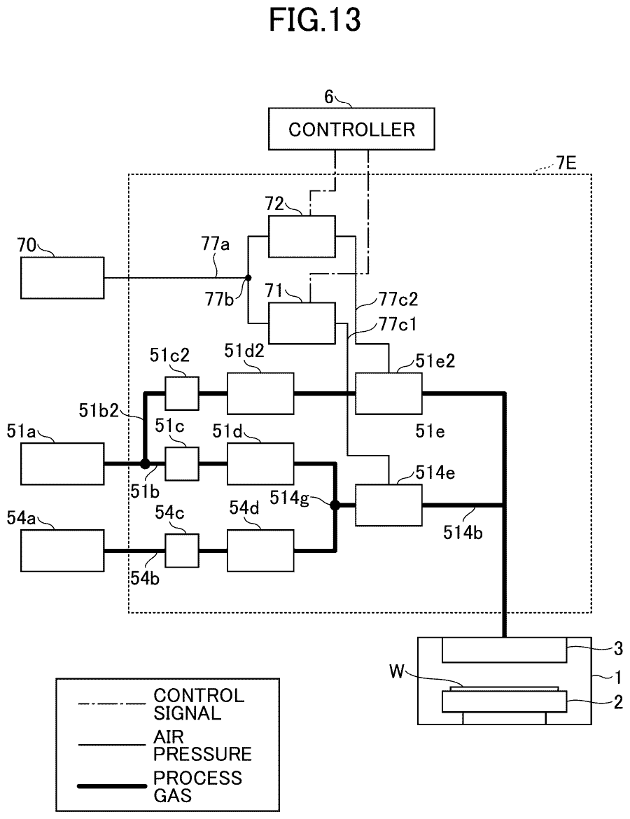

Next, an example of a gas supply timing adjustment mechanism 7E of a film forming apparatus according to a sixth embodiment will be described with reference to FIG. 13. FIG. 13 is an example of a configuration diagram of the gas supply timing adjustment mechanism 7E of the film forming apparatus according to the sixth embodiment.

The gas supply timing adjustment mechanism 7E according to the sixth embodiment illustrated in FIG. 13 has a configuration (including a gas supply line 51b2, a flow rate controller 51c2, a storage tank 51d2, a valve 51e2, and a solenoid valve 72) in which only the first source gas (TiCl₄ gas) is supplied into the processing chamber 1, in addition to a configuration in which the first source gas (TiCl₄ gas) and the second source gas (SiH₄ gas) are supplied simultaneously into the processing chamber 1 as illustrated in the gas supply timing adjustment mechanism 7A according to the second embodiment illustrated in FIG. 7.

Specifically, one end of the gas supply line 51b2 branches from a gas supply line 51b upstream of a flow rate controller 51c, and the other end of the gas supply line 51b2 merges with a gas supply line 514b downstream of a valve 514e and is connected to the showerhead 3. The gas supply line 51b2 is provided with the flow rate controller 51c2, the storage tank 51d2 (a third storage tank), and the valve 51e2 (a second opening and closing valve) in this order from the upstream side.

The flow rate controller 51c2 , the storage tank 51d2, and the valve 51e2 provided in the gas supply line 51b2 are the same as the flow rate controller 51c2, the storage tank 51d2, and the valve 51e2 provided in the gas supply line 51b2 of the gas supply timing adjustment mechanism 7C according to the fourth embodiment (see FIG. 9), and thus a duplicate description thereof will be omitted.

Pneumatic supply lines 77a, 77c1, and 77c2 supply compressed air pressure from an air supply source 70 to pilot ports of the valves 514e and 51e2. One end of the pneumatic supply line 77a is connected to the air supply source 70 and the other end of the pneumatic supply line 77a is connected to a branch part 77b. The other end of the pneumatic supply line 77a, one end of the pneumatic supply line 77c1, and one end of the pneumatic supply line 77c2 are connected to the branch part 77b. That is, the branch part 77b branches the pneumatic supply line 77a into the pneumatic supply line 77c1 and the pneumatic supply line 77c2. The other end of the pneumatic supply line 77c1 is connected to the pilot port of the valve 514e. The other end of the pneumatic supply line 77c2 is connected to the pilot port of the valve 51e2.

A solenoid valve 71 is an opening and closing valve provided in the pneumatic supply line 77c1 (a first pneumatic supply line). A solenoid valve 72 is an opening and closing valve provided in the pneumatic supply line 77c2 (a second pneumatic supply line).

When the solenoid valve 71 is opened, compressed air is supplied to the valve 514e. When the solenoid valve 72 is opened, compressed air is supplied to the valve 51e2.

According to the gas supply timing adjustment mechanism 7E according to the sixth embodiment, similar to the gas supply timing adjustment mechanism 7C according to the fourth embodiment, the step of simultaneously supplying the first source gas (TiCl₄ gas) and the second source gas (SiH₄ gas) to the processing chamber 1 and the step of supplying only the first source gas (TiCl₄ gas) to the processing chamber 1 can be performed.

Although the film forming apparatuses have been described above, the present disclosure is not limited to the above-described embodiments, and various modifications and improvements can be made within the scope of the present disclosure described in the claims.

While certain embodiments have been described, these embodiments have been presented by way of example only, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

According to an embodiment of the present disclosure, a film forming apparatus that stably and simultaneously supplies a plurality of process gases can be provided.

What is claimed is:

1. A film forming apparatus for supplying a first source gas, a second source gas, and a reaction gas into a processing chamber, the film forming apparatus comprising:
a gas supply timing adjustment mechanism configured to simultaneously supply the first source gas and the second source gas into the processing chamber; and
a controller configured to control the gas supply timing adjustment mechanism.

2. The film forming apparatus according to claim 1, wherein
the gas supply timing adjustment mechanism includes:
a first storage tank configured to store the first source gas;
a second storage tank configured to store the second source gas;
a first opening and closing valve provided in a first gas supply line and configured to be opened and closed by air actuation, the first gas supply line extending from the first storage tank to the processing chamber;
a second opening and closing valve provided in a second gas supply line and configured to be opened and closed by air actuation, the second gas supply line extending from the second storage tank to the processing chamber; and
a first solenoid valve provided upstream of a branch part of a pneumatic supply line, the pneumatic supply line being configured to branch compressed air supplied from an air supply source at the branch part and supply compressed air pressure to the first opening and closing valve and the second opening and closing valve, and
the controller is configured to control opening and closing of the first solenoid valve.

3. The film forming apparatus according to claim 1, wherein
the gas supply timing adjustment mechanism includes:
a first storage tank configured to store the first source gas;
a second storage tank configured to store the second source gas;
an opening and closing valve provided downstream of a merging part of a gas supply line and configured to be opened and closed by air actuation, the gas supply line being configured to merge the first source gas supplied from the first storage tank and the second source gas supplied from the second storage tank at the merging part and supply the first source gas and the second source gas into the processing chamber; and
a first solenoid valve provided in a pneumatic supply line configured to supply compressed air pressure from an air supply source to the opening and closing valve, and
the controller is configured to control opening and closing of the first solenoid valve.

4. The film forming apparatus according to claim 1, wherein
the gas supply timing adjustment mechanism includes:
a first storage tank configured to store the first source gas and the second source gas;
a first opening and closing valve provided in a gas supply line and configured to be opened and closed by air actuation, the gas supply line extending from the first storage tank to the processing chamber; and
a first solenoid valve provided in a first pneumatic supply line configured to supply compressed air pressure from an air supply source to the first opening and closing valve, and
the controller is configured to control opening and closing of the first solenoid valve.

5. The film forming apparatus according to claim 2, wherein
the gas supply timing adjustment mechanism includes:
a third storage tank configured to store the first source gas;
a third opening and closing valve provided in a gas supply line and configured to be opened and closed by air actuation, the gas supply line extending from the third storage tank to the processing chamber; and
a second solenoid valve provided in a second pneumatic supply line configured to supply compressed air pressure from the air supply source to the third opening and closing valve, and
the controller is configured to control opening and closing of each of the first solenoid valve and the second solenoid valve.

6. The film forming apparatus according to claim 3, wherein
the gas supply timing adjustment mechanism includes:
a third storage tank configured to store the first source gas;
a second opening and closing valve provided in a gas supply line and configured to be opened and closed by air actuation, the gas supply line extending from the third storage tank to the processing chamber; and
a second solenoid valve provided in a second pneumatic supply line configured to supply compressed air pressure from the air supply source to the second opening and closing valve, and
the controller is configured to control opening and closing of each of the first solenoid valve and the second solenoid valve.

7. The film forming apparatus according to claim 4, wherein
the gas supply timing adjustment mechanism includes:
a second storage tank configured to store the first source gas;
a second opening and closing valve provided in a gas supply line and configured to be opened and closed by air actuation, the gas supply line extending from the second storage tank to the processing chamber; and
a second solenoid valve provided in a second pneumatic supply line configured to supply compressed air pressure from the air supply source to the second opening and closing valve, and
the controller is configured to control opening and closing of each of the first solenoid valve and the second solenoid valve.

8. The film forming apparatus according to claim 2, wherein the controller is configured to perform control to:
supply the first source gas and the second source gas into the processing chamber by controlling the first solenoid valve; and
supply the reaction gas into the processing chamber.

9. The film forming apparatus according to claim 5, wherein the controller is configured to perform control to:
supply the first source gas and the second source gas into the processing chamber by controlling the first solenoid valve;
supply the first source gas into the processing chamber by controlling the second solenoid valve; and
supply the reaction gas into the processing chamber.

10. The film forming apparatus according to claim 1, wherein
the first source gas is a metal-containing gas containing a metal element,
second source gas is a silicon-containing gas containing a silicon element, and
the reaction gas is a nitrogen-containing gas containing a nitrogen element.

11. The film forming apparatus according to claim 1, wherein
the first source gas is TiCl₄,
the second source gas is SiH₄,
the reaction gas is NH₃, and
a TiSiN film is formed on a substrate placed on a stage in the processing chamber.
